(19) United States
(12) Patent Application Publication
(10) Pub. No.: US 2004/0189146 A1
(43) Pub. Date: Sep. 30, 2004

(54) Surface acoustic wave device and method of fabricating the same

(75) Inventors: Masanori Ueda, Yokohama (JP); Osamu Kawachi, Yokohama (JP); Michio Miura, Kawasaki (JP); Suguru Warashina, Kawasaki (JP)

Correspondence Address: ARENT FOX KINTNER PLOTKIN & KAHN, PLLC, Suite 400, 1050 Connecticut Avenue, N.W., Washington, DC, 20036-5339, US

(73) Assignees: FUJITSU MEDIA DEVICES LIMITED; FUJITSU LIMITED

(21) Appl. No.: 10/809,867

(22) Filed: Mar. 26, 2004

(30) Foreign Application Priority Data
Mar. 28, 2003 (JP) 2003-090497

(51) Int. Cl. H02N 2/00; H01L 41/04; H01L 41/08; H01L 41/18

(52) U.S. Cl. 310/313 A; 310/313 R

(57) ABSTRACT

A method of fabricating a surface acoustic wave device includes the steps of: joining a supporting substrate to a second surface of a piezoelectric substrate opposite to a first surface thereof; grinding and polishing the first surface of the piezoelectric substrate; grinding and polishing a third surface of the supporting substrate opposite to another surface thereof to which the second surface of the piezoelectric substrate is joined; and forming, on the first surface of the piezoelectric substrate, an on-chip pattern including comb-like electrodes and electrode pads.

### BACKGROUND OF THE INVENTION

1. Field of the Invention

The invention generally relates to a surface acoustic wave device and a method of fabricating the same, and more particularly, to a surface acoustic wave device equipped with a surface acoustic wave chip housed in a package, and a method of fabricating such a surface acoustic wave device.

2. Description of the Related Art

Recently, there has been a demand to downsize electronic elements mounted to electronic devices and improve the performance thereof with downsizing and high performance of the electronic devices. For instance, there have been similar demands on surface acoustic wave (SAW) devices that are electronic parts used as filters, delay lines, oscillators in electronic devices capable of transmitting and receiving radio waves. The SAW devices are used in a radio frequency (RF) part of the cellular phone or the like in order to attenuate undesired signals.

It is also required to reduce the production cost of SAW devices under a situation that demands on SAW devices increase rapidly due to expanded applications.

A conventional filter device using a SAW chip will now be described with reference to FIGS. 1A and 1B. The following filter device is disclosed in Japanese Laid-Open Patent Application Publication No. 2001-110946. FIG. 1A shows a SAW chip 110, and FIG. 1B shows a SAW filter 100 equipped with the SAW chip 110. FIG. 1B is a cross-sectional view taken along an orthogonal line on the main surface of the SAW filter 100.

As shown in FIG. 1A, the SAW chip 110 has a substrate 111 made of a piezoelectric substrate (hereinafter, referred to as piezoelectric substrate), comb-like electrodes 113, and electrode pads 114 connected to the comb-like electrodes 113 via a wiring pattern (not shown). The comb-like electrodes 113 on the piezoelectric substrate 111 form an interdigital transducer (IDT). For example, the piezoelectric substrate 111 is 350 μm thick, and is formed by a piezoelectric single-crystal substrate of a 42° Y-cut X-propagation lithium tantalate (LiTaO₃: LT). The LT substrate has a linear expansion coefficient of 16.1 ppm/° C. in the X direction in which the SAW is propagated. The LT substrate may be replaced by a piezoelectric single-crystal substrate of Y-cut lithium niobate (LiNbO₃: LN).

The IDT 113, electrode pads 114 and wiring pattern are simultaneously formed on the main surface (upper surface) of the piezoelectric substrate 111 by sputtering or the like. These patterns may be formed by a single conductive film that contains at least one of gold (Au), aluminum (Al), copper (Cu), titanium (Ti), chromium (Cr) and tantalum (Ta). The patterns may also be formed by a laminate of conductive layers, each of which contains at least one of Au, Al, Cu, Ti, Cr and Ta.

The SAW filter 100 shown in FIG. 1B is equipped with the SAW chip 110, which is flip-chip mounted on a die attachment surface that is the bottom of a cavity 109 formed in a package 102. Electrode pads 114 of the SAW chip 110 are bonded to electrode pads 105 formed on the die attachment surface via bumps 108. This bonding electrically connects the pads 114 and 105, and mechanically fixes the SAW chip 110 to the package 102. The electrode pads 105 are electrically connected to a foot pattern 107 formed on the backside of the package 102 through via-wiring lines 106 that penetrate the bottom portion of the package 102. In this manner, the input and output terminals of the SAW chip 110 can be drawn to the backside of the package 102.

A cap 103 hermetically seals the cavity 109 that houses the SAW chip 110. Conventionally, resin or metal is used as an adhesive agent for bonding the package 102 and the cap 103.

However, the LT or LN substrate for the piezoelectric substrate 111 is fragile as compared to silicon generally used in the semiconductor techniques. For instance, the LT or LN substrate cannot be made thinner than approximately 250 μm by grinding and polishing in terms of mass productivity. If the LT or LN substrate is made thinner than the above limit, it may be cracked or broken in a post process, and is thus required to be handled very nervously.

### SUMMARY OF THE INVENTION

It is a general object of the present invention to provide a surface acoustic wave device and a method of fabricating the device.

A more specific object of the present invention is to provide a compact, easily producible surface acoustic wave device and a method of fabricating the same.

These objects of the present invention are achieved by a method of fabricating a surface acoustic wave device comprising the steps of: (a) joining a supporting substrate to a second surface of a piezoelectric substrate opposite to a first surface thereof; (b) grinding and polishing the first surface of the piezoelectric substrate; (c) grinding and polishing a third surface of the supporting substrate opposite to another surface thereof to which the second surface of the piezoelectric substrate is joined; and (d) forming, on the first surface of the piezoelectric substrate, an on-chip pattern including comb-like electrodes and electrode pads.

The above objects of the present invention are also achieved by a surface acoustic wave device comprising: a piezoelectric substrate having a first surface on which an on-chip pattern including comb-like electrodes and electrode pads is formed; and a supporting substrate joined to a second surface of the piezoelectric substrate opposite to the first surface thereof, at least one of the first surface of the piezoelectric substrate and a third surface of the supporting substrate opposite to a fourth surface thereof joined to the second surface of the piezoelectric substrate is a grinded and polished surface.

### BRIEF DESCRIPTION OF THE DRAWINGS

Other objects, features and advantages of the present invention will become more apparent from the following detailed description when read in conjunction with the accompanying drawings, in which:

FIGS. 1A and 1B show a conventional SAW device;

FIGS. 2A, 2B and 2C show an outline of the present invention;

FIGS. 3A and 3B show a surface activation process usable in the present invention;

FIG. 4A is a plan view of a combined substrate composed of a piezoelectric substrate and a silicon substrate on which on-chip patterns 1a are arranged in rows and columns;

FIG. 4B is a plan view of a substrate having package-side patterns are arranged in rows and columns;

FIG. 5A is a perspective view of a SAW device according to a first embodiment of the present invention;

FIG. 5B is a cross-sectional view taken along a line A-A shown in FIG. 5A;

FIGS. 6A through 6F show a process of fabricating a SAW chip according to the first embodiment of the present invention;

FIGS. 7A through 7H show a process of producing packages and SAW devices according to the first embodiment of the present invention;

FIG. 8A is a perspective view of a SAW device according to a second embodiment of the present invention;

FIG. 8B is a cross-sectional view taken along a line B-B shown in FIG. 8A;

FIGS. 9A through 9F show a process of fabricating the SAW device according to the second embodiment of the present invention;

FIGS. 10A through 10G show a process of fabricating the SAW device shown in FIGS. 8A and 8B according to a third embodiment of the present invention; and

FIGS. 11A through 11D show a process of fabricating the SAW device shown in FIGS. 8A and 8B according to a fourth embodiment of the present invention.

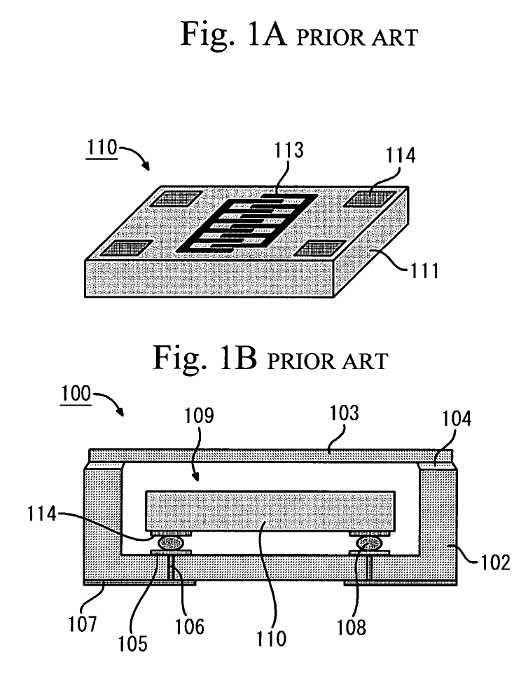

### DESCRIPTION OF THE PREFERRED EMBODIMENTS

A description will now be given of an outline of the present invention.

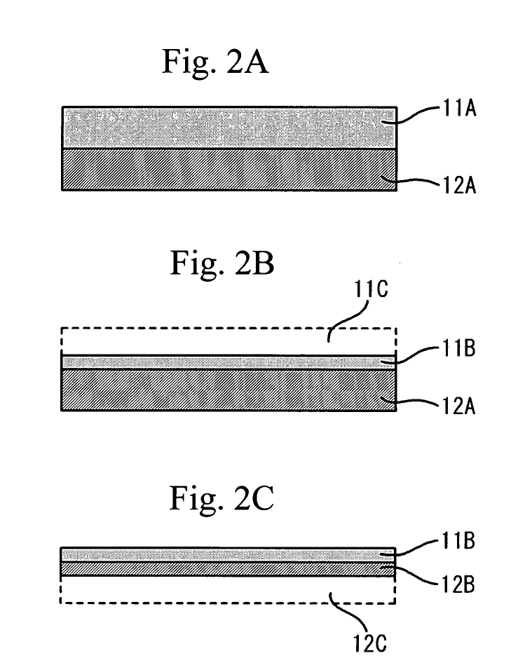

Referring to FIG. 2A, a piezoelectric substrate 11A that is comparatively thick and a silicon substrate 12A that is, for example, as thick as the piezoelectric substrate 12A are joined. The piezoelectric substrate 11A is grinded and polished so that a portion 11B remains while a portion 11C is removed, as shown in FIG. 2B. The silicon substrate 12A, which serves as a supporting substrate, is grinded and polished so that a portion 12B remains while a portion 12C is removed. The resultant silicon substrate 12B has a larger strength and elasticity than the resultant piezoelectric substrate 11B. Thus, the strength of the piezoelectric substrate 11B can be reinforced by the silicon substrate 12B. This makes it possible to make the piezoelectric substrate 12B thinner than the conventional piezoelectric substrate. This means that the joined substrate composed of the substrates 11B and 12B is also thin, as compared to the conventional substrate. Nevertheless, the joined substrate can be reliably applied to the conventional SAW production process.

The piezoelectric substrate 11A may, for example, be a single crystal of 42° Y-cut X-propagation lithium tantalate, which has a linear expansion coefficient of 16.1 ppm/° C. in the X direction in which the SAW is propagated. It is also possible to use a single crystal of Y-cut lithium niobate, quartz or another piezoelectric material. For instance, the piezoelectric substrate 11A is approximately 350 μm thick, and the silicon substrate 12A is approximately 200 μm thick from viewpoints of easy handling.

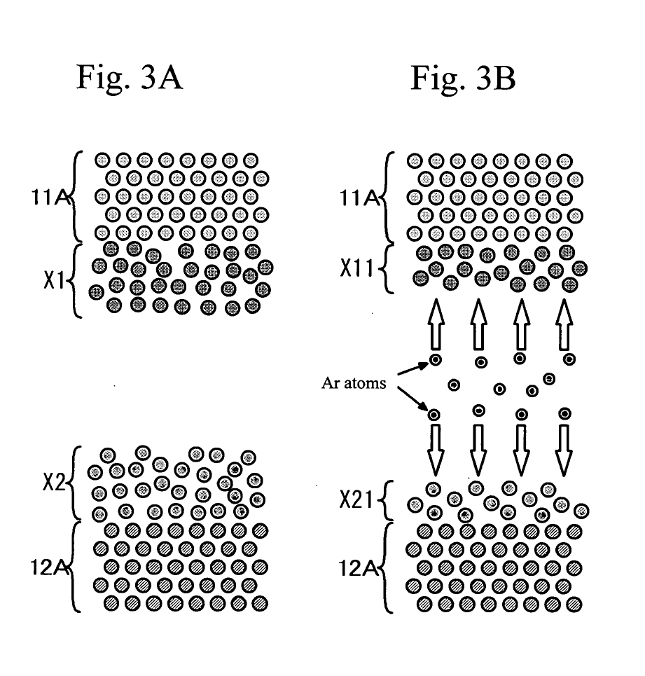

An adhesive may be used to join the substrates 11A and 12A. However, it is preferable to directly bond the substrates 11A and 12A. In this case, the bonding strength can be enhanced by applying a surface activation process to the joining surfaces of the substrates 11A and 12A. Now, a description will be given, with reference to FIGS. 3A and 3B, of the joining method that employs the surface activation process.

Referring to FIG. 3A, both of the substrates 11A and 12A are cleaned through RCA cleaning or the like, so that impurities X1 and X2 including compounds and adsorbate that adhere to the surfaces, especially the joining surfaces, are removed (cleaning process). RCA cleaning is one of the techniques that utilize solutions such as a cleaning solution of ammonia, hydrogen peroxide, and water, mixed at a volume mixing ratio of 1:1-2:5-7, and a cleaning solution of hydrochloric acid, hydrogen peroxide, and water, mixed at a volume mixing ratio of 1:1-2:5-7.

After the cleaned substrates are dried (drying process), as shown in FIG. 3B, the joining surfaces of the substrates 11A and 12A are exposed to ion beams, neutralized high-energy atom beams, or plasma of inert gas such as argon (Ar) or oxygen, so that residual impurities X11 and X21 are removed, and that the surfaces can be activated (activation process). The particle beams or plasma to be used are selected according to the materials of the substrates to be joined.

The piezoelectric substrate 11A and the silicon substrate 12A are then positioned and joined to each other (joining process). For most materials, this joining process is carried out in a vacuum or in an atmosphere of a high purity gas such as an inert gas, though it may be carried out in the air. Also, it might be necessary to press the substrates 11A and 12A from both sides. This joining process can be carried out at room temperature or by heating the substrates 11A and 12A at a temperature of 100° C. or lower. The use of heating may increase the joining strength of the substrates 11A and 12A.

The present method does not need an annealing process at 1000° C. or higher after the substrates 11A and 12A are joined. Thus, the substrates 11A and 12A can be reliably joined without any damage. In addition, the method with the surface activation process does not need any adhesive agent such as resin or metal and realizes a height-reduced package, so that downsizing of package can be achieved.

As described above, the piezoelectric substrate 11A and the silicon substrate 12A are joined and are then grinded and polished so as to be as thin as possible so long as the joined substrate is not damaged. The silicon substrate 12A (12B) functions to not only restrain a change of the piezoelectric substrate 11A (11B) in terms of constants including the thermal expansion coefficient but also to enhance the strength of the joined substrate. It should be noted that the piezoelectric substrate 11B after grinding and polishing can be made thinner than the piezoelectric substrate alone. The piezoelectric substrate 11B may be tens of μm to 100 μm thick, and the silicon substrate 12B may be tens of μm to 100 μm thick as well. Thus, the joined substrate is 100 μm to hundreds of μm thick. The silicon substrate 12A may be totally removed by grinding and polishing in case where only a small mechanical or thermal load is applied to the piezoelectric substrate. This holds true for a piezoelectric substrate on which an on-chip pattern 1a is formed on the piezoelectric substrate 11A, as will be described later. The use of such a piezoelectric substrate enables the SAW chip to be made thinner.

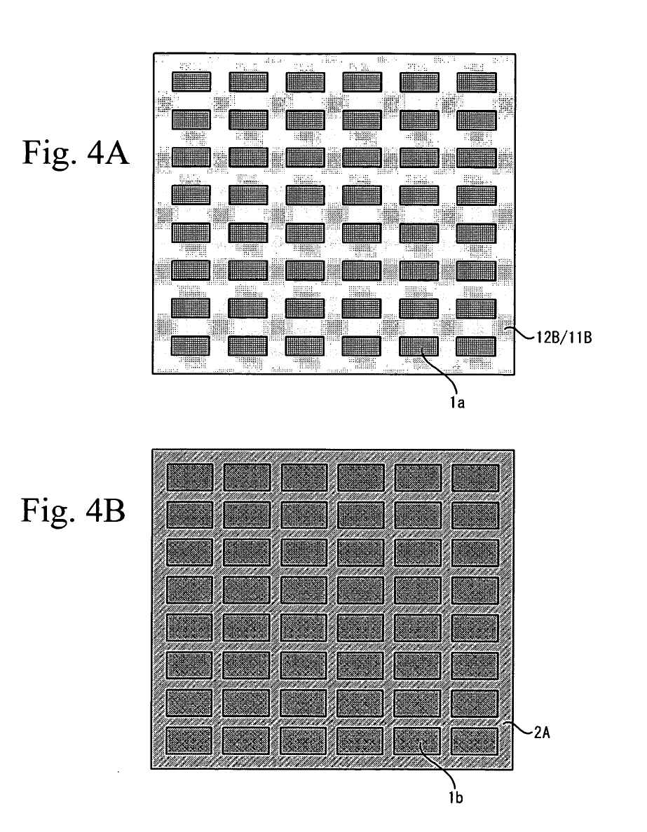

As shown in FIG. 4A, a plurality of on-chip patterns 1a may be formed on the joined substrate in rows and columns. Each of the patterns 1a corresponds to a respective SAW device. As will be described later, a silicon substrate 2A that has patterns 1b arranged in rows and columns may be used together with the joined substrate to efficiently produce many SAW devices at a time. This leads to cost reduction.

(First Embodiment)

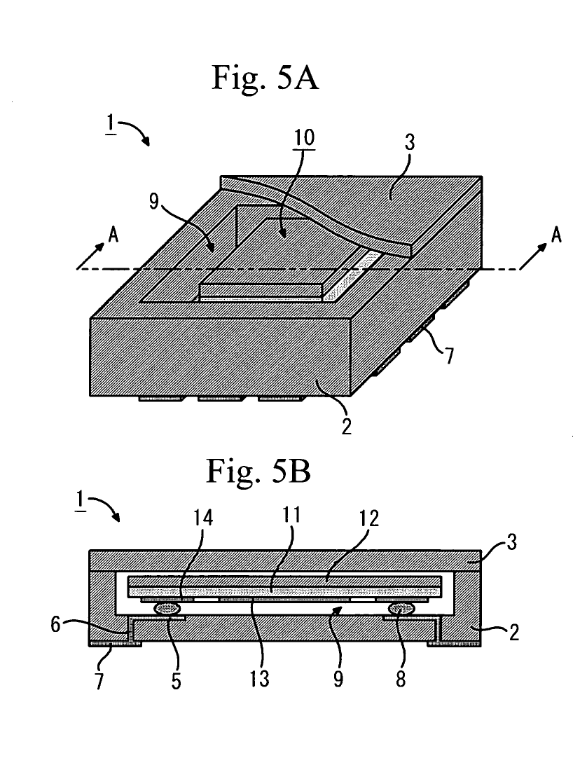

A description will be given, with reference to FIGS. 5A and 5B, of a SAW device 1 according to a first embodiment of the present invention. FIG. 5A is a perspective view of the SAW device 1, and FIG. 5B is a cross-sectional view taken along a line A-A shown in FIG. 5A.

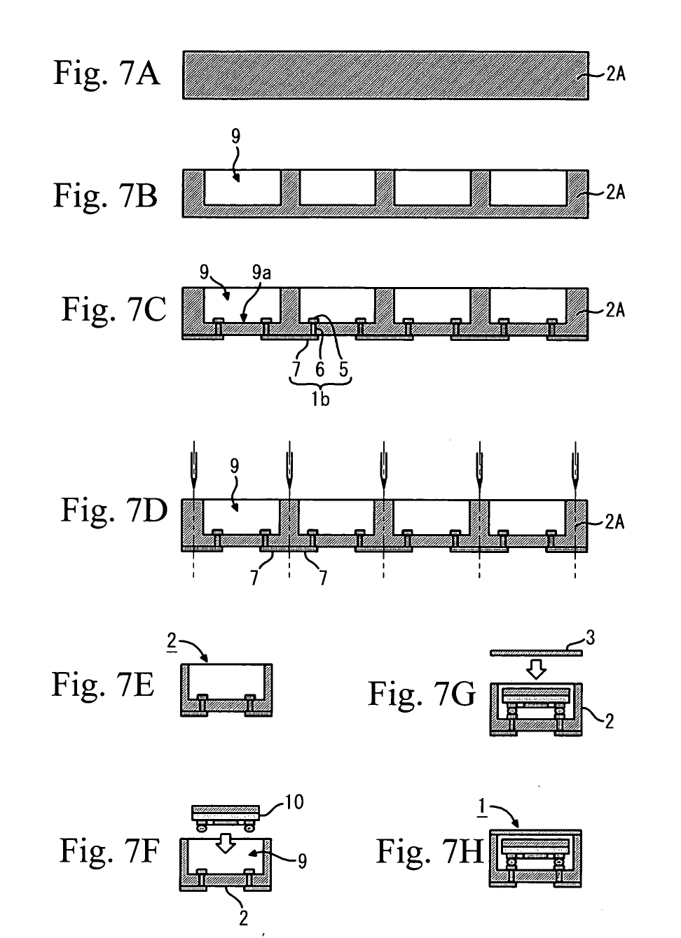

Referring to FIG. 5A, a SAW chip 10 is flip-chip mounted to a package 2 so that a circuit surface of the SAW chip 10 faces the bottom of a cavity 9 formed in the package 2. On the circuit surface of the SAW chip 10, formed are at least one IDT 13 and electrode pads 14. The bottom of the cavity 9 corresponds to a die attachment surface 9a shown in FIG. 7C, which will be described later. The package 2 may be made of, as the major component, at least one of silicon, ceramics, aluminum ceramics, BT (Bismuthimido-Triazine) resin, PPE (Polyphenylene-Ethel), polyimide resin, glass-epoxy and glass-cloth. The first embodiment employs silicon for the package 2. Preferably, the package 2 is made of a silicon substance that has a resistivity of 100 Ω·m or greater in order to avoid degradation of the filter characteristic stemming from the resistance of silicon.

The cavity 9 is hermetically sealed with a cap 3, which may be made of, as the major component, at least one of silicon, metal ceramics, aluminum ceramics, BT resin, PPE, polyimide resin, glass-epoxy and glass-cloth. Like the package 2, preferably, the cap 3 made of silicon has a resistivity of 100 Ω·m or greater in order to avoid degradation of the filter characteristic stemming from the resistance of silicon. The cap 3 may be joined to the package 2 by an adhesive. However, it is preferable to employ the aforementioned surface activation process.

As shown in FIG. 5B, electrodes or terminals for signal inputting and outputting on the SAW chip 10 are extended to the backside of the package in such a manner that electrode pads 14 on the SAW chip 10 are electrically connected to the foot pattern 7 formed on the backside of the package 2 via a given pattern provided to the package, which pattern includes electrode pads 5 and via-wiring lines 6. The electrode pads 5 and 14 are electrically and mechanically connected together by means of metal bumps 8, which contain a major component of gold, aluminum, copper or the like. This mechanically fixes the SAW chip 10 to the package 2 and electrically connects the SAW chip 10 to the pattern on the package 2.

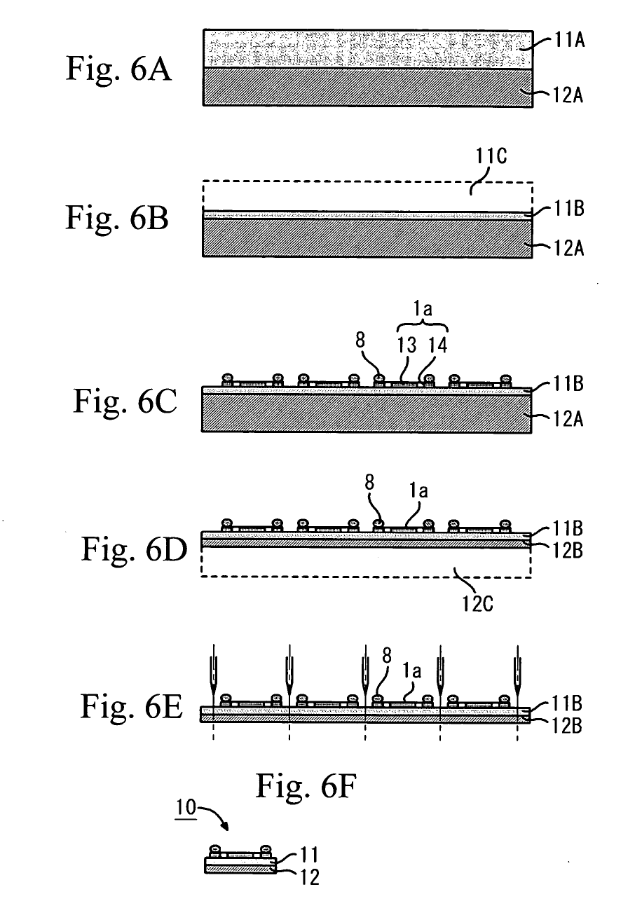

A description will now be given, with reference to FIGS. 6A through 6F and 7A through 7H, of a method of fabricating the SAW device 1.

FIGS. 6A through 6F show a process of fabricating the SAW chip 10 embedded in the SAW device 1. FIG. 6A shows a substrate joining step in which the piezoelectric substrate 11A (which is, for example, 350 μm thick) and the silicon substrate 12A (which is, for example, 200 μm thick) are subjected to the surface activation process and are then joined together. The next step is a piezoelectric substrate grinding and polishing step, which grinds and polishes the piezoelectric substrate 11A so as to have a given thickness within the range of tens of μm to 100 μm.

Next, as is shown in FIG. 6B, the on-chip patterns 1a are photolithographically formed on the piezoelectric substrate 11B. The patterns 1a include the IDT 13, the electrode pads 14 and the wiring pattern. Then, the bumps 8 used for bonding are provided on the electrode pads 14.

Then, as is shown in FIG. 6C, the silicon substrate 12A is grinded and polished so that the resultant silicon substrate 12B has a given thickness. The removed portion of the silicon substrate 12A is indicated by the reference numeral 12C. After that, the joined substrate is divided into parts by cutting, each of which parts includes a respective on-chip pattern 1a. A dicing blade or laser beam may be used for cutting.

After the on-chip pattern 1a and the bumps 8 are formed on the piezoelectric substrate 11B, the silicon substrate 12A joined to the backside of the piezoelectric substrate 11B is grinded and polished so as to result in the silicon substrate 12B having the given thickness, as shown in FIG. 6D. Then, as shown in FIG. 6E, the piezoelectric substrate 11B and the silicon substrate 12B that are joined are cut into the individual on-chip patterns 1a so that the separate SAW chips 10, each of which is as shown in FIG. 6F, can be produced. The cutting process may employ the dicing blade or laser beam.

The separate SAW devices 10 are flip-chip mounted in the packages 2 by a process shown in FIGS. 7A through 7F.

Referring to FIG. 7A, a silicon substrate 2A is prepared for producing the packages 2. The substrate 2A may be made of any of the aforementioned substances. Next, as shown in FIG. 7B, cavities 9 are formed in the silicon substrate 2A by, for example, reactive ion etching (preferably, deep RIE). Then, as shown in FIG. 7C, the electrode pads 5, via-wiring lines 6 and foot patterns 7, which may be defined as cavity-side patterns 1b all together, are formed on and in the silicon substrate 2A. The electrode pads 5 are formed on the die attachment surfaces 9a defined by the bottoms of the cavities 9. The electrode pads 5 may be bonded to the electrode pads 14 of the SAW chips 10 via the bumps 8. The via-wiring lines 6 extend to the backsides of the individual packages 2 opposite to the surfaces that define the cavities 9. The foot patterns 7 have contacts with the via-wiring lines 6. Preferably, the foot patterns 7 are formed so as to extend over the adjacent packages.

Then, as shown in FIG. 7D, the silicon substrate 2A is cut into the individual package-side patterns 1b, so that the separate packages 2 each shown in FIG. 7E can be produced. The cutting process may employ the dicing blade or laser beam.

The SAW chips 10 are facedown bonded to the cavities 9 of the packages 2, as shown in FIG. 7F. Subsequently, the cavities 9 are hermetically sealed with the caps 3, so that the SAW devices 1 are completed as shown in FIG. 7H. Although the caps 3 may be bonded to the packages by using an adhesive such as resin, it is preferable to use the bonding method with the surface activation process. Preferably, the caps 3 may be made of silicon for the silicon packages 2 subject to the surface activation process. This improves the bonding strength. Metal films made of, for example, gold, may be formed on the bonding surfaces of the packages 2 and the caps 3 in advance of bonding. The use of such metal films will avoid some limits on selection of materials for the packages 2 and the caps 3 and realize tight bonding.

As described above, the thinner SAW chips 10 can be fabricated by using the joined substrate composed of the piezoelectric substrate 11B and the silicon substrate 12B. Accordingly, the packages 2 for housing the SAW chips 10 can be thinned, so that the thinner SAW devices 1 can be produced. The use of the joined substrate does not need any complicate production process. The use of the surface activation process does not need any adhesive such as resin, and facilitates thinning of the SAW chips 10. Further, the sufficient bonding strength can be achieved by a narrower bonding area than that for the use of adhesive, so that the SAW devices 1 can be downsized. The differences in thermal expansion coefficient and Young's modulus between the piezoelectric substrate 11B and the silicon substrate 12B restrain thermal expansion of the piezoelectric substrate 11B, so that the piezoelectric substrate 11B can be stabilized and the filter characteristic of the SAW chip 10 can also be stabilized.

(Second Embodiment)

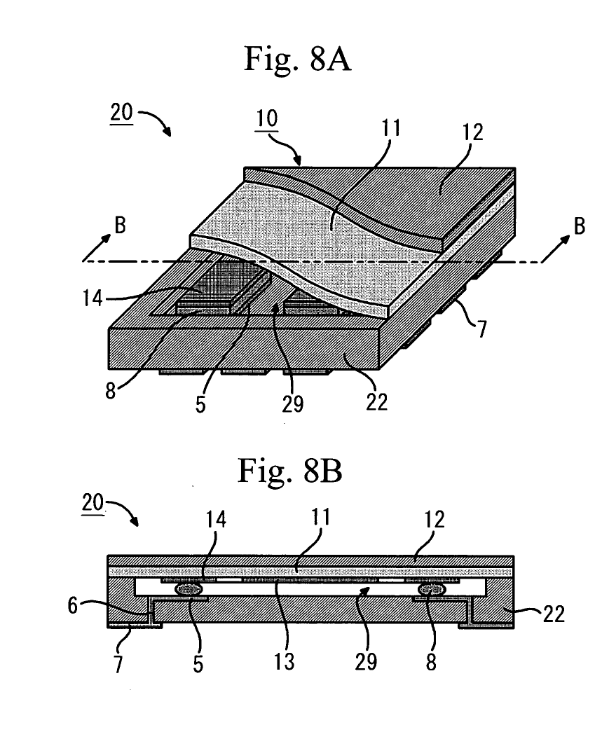

A description will now be given of a second embodiment of the present invention. FIG. 8A is a perspective view of a SAW device 20 according to the second embodiment of the present invention, and FIG. 8B is a cross-sectional view taken along a line B-B shown in FIG. 8A.

Referring to FIG. 8A, the piezoelectric substrate 11 of a SAW chip 10 joined to the silicon substrate 12 serves as a cap that hermetically seals a cavity 29 formed in a package 22. Like the package 2, the package 22 may be made of, as the major component, at least one of silicon, metal ceramics, aluminum ceramics, BT resin, PPE, polyimide resin, glass-epoxy and glass-cloth. Preferably, the silicon substrate has a resistivity of 100 Ω·m or greater in order to avoid degradation of the filter characteristic stemming from the resistance of silicon. The piezoelectric substrate 11 may be joined to the package 22 by an adhesive. However, it is preferable to employ the aforementioned surface activation process.

The pads 14 connected to the input and output terminals of the SAW chip 10 are electrically and mechanically connected to the electrode pads 5 that are parts of the package-side pattern via the metal bumps 8 containing, for example, gold, aluminum or copper as the major component. The pads 5 are electrically connected to the foot patterns 7 via the via-wiring lines 6, so that the SAW chip 10 is electrically accessible from the backside of the package 22.

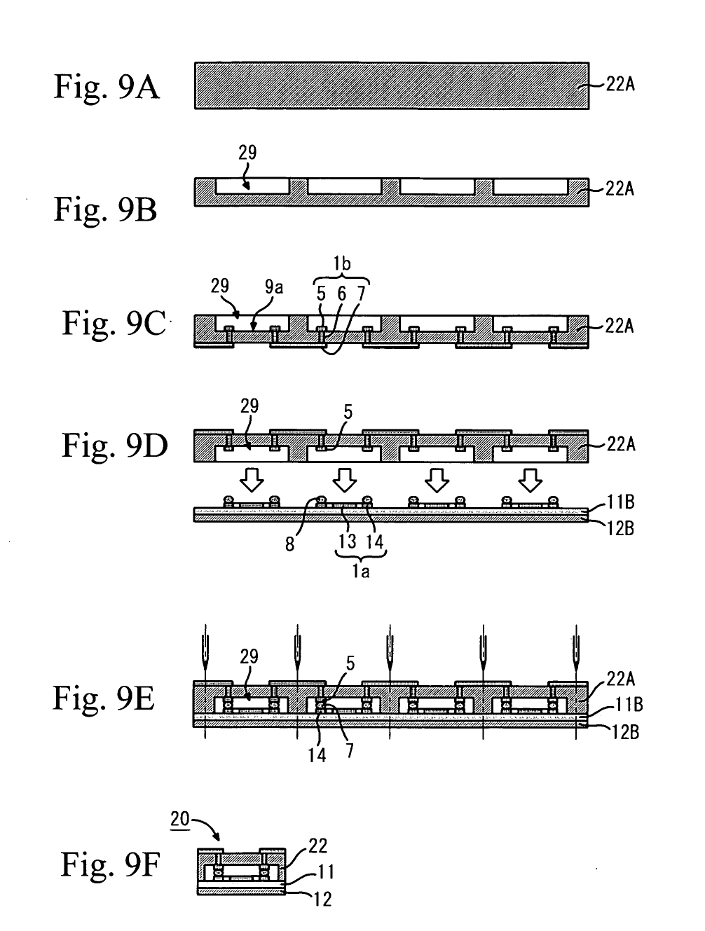

The SAW device 20 can be fabricated as shown in FIGS. 9A through 9F. A substrate 22A made of any of the aforementioned substances is prepared for producing multiple packages 22. For example, the substrate 22A is a silicon substrate. Next, as shown in FIG. 9B, cavities 29 are formed in the silicon substrate 22A by deep RIE or the like. The cavities 29 are not required to have a depth that allows the SAW chip 10 to be completely housed. More specifically, the connections between the electrode pads 14 of the SAW chips 10 and the electrode pads 5 of the packages 22 can be made using the bumps 8 within the cavities 29. The IDTs 13, the electrode pads 14 and the wiring pattern of the SAW chip 10 do not touch the bottoms of the cavities 29 (die attachment surfaces 9a) when assembled. Then, as shown in FIG. 9C, the package-side pattern 1b is formed which includes the electrode pads 5, the via-wiring lines 6 and the foot patterns 7. The pads 5 are electrically connected to the foot patterns 7 via the via-wiring lines 6, so that the SAW chip 10 is electrically accessible from the backside of the package 22. The foot patterns 7 are formed so as to extend over the adjacent packages.

After the package-side pattern 1b is provided for the silicon substrate 22A, the joined substrate composed of the piezoelectric substrate 11B and the silicon substrate 12B is joined to the silicon substrate 22A so that the on-chip patterns 1a including the IDTs 13 and the pads 14 are housed in the cavities 29. Although this joining may use adhesive such as resin, but the joining method with the aforementioned surface activation process may be used. The on-chip patterns 1a shown in FIG. 6D correspond to the cavities 29 in position. In the joining process, the electrode pads 5 on the die attachment surfaces of the cavities 29 are brought into contact with the corresponding electrode pads 14 on the joined substrate via the bumps 8.

Then, as shown in FIG. 9E, the joined substrate composed of the silicon substrate 22A, the piezoelectric substrate 11B and the silicon substrate 12B is cut into the individual SAW devices 20 separate from each other, as shown in FIG. 9F. The cutting process may use the dicing blade or laser beam.

As described above, the thinner SAW chips 10 can be fabricated by using the joined substrate composed of the piezoelectric substrate 11B and the silicon substrate 12B. Accordingly, the packages 22 for housing the SAW chips 10 can be thinned, so that the thinner SAW devices 20 can be produced. The use of the joined substrate does not need any complicate production process. The use of the surface activation process does not need any adhesive such as resin, and facilitate thinning of the SAW chips 10. Further, the sufficient bonding strength can be achieved by a narrower bonding area than that for the use of adhesive, so that downsizing of the SAW devices 20 can be realized. The differences in thermal expansion coefficient and Young's modulus between the piezoelectric substrate 11B and the silicon substrate 12B restrain thermal expansion of the piezoelectric substrate 11B, so that the piezoelectric substrate 11B can be stabilized and the filter characteristic of the SAW chip 10 can also be stabilized. In addition, the piezoelectric substrate 11 and the silicon substrate 12 of each SAW device 20 serve as the cap that hermetically seals the cavity 29. This avoids the dead space that will be occupied due to the use of the separate cap, and facilitates further thinning.

(Third Embodiment)

A third embodiment of the present invention is directed to anther method of fabricating the SAW devices 20 that have been described with reference to FIGS. 8A and 8B.

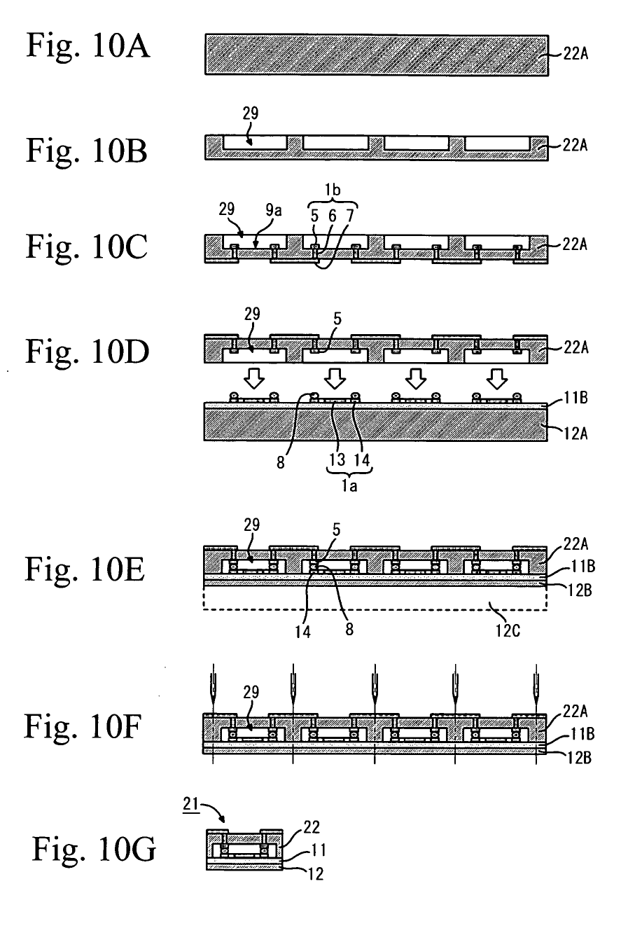

FIGS. 10A through 10G show the third embodiment. The steps of Figs. 10A through 10C are the same as those shown in FIGS. 9A through 9C. The step of FIG. 10D differs from that of FIG. 9D. The joined substrate has the silicon substrate 12A that has not yet been grinded and polished. After the joined substrate is joined to the substrate 22A, the silicon substrate 12A is grinded and polished so as to remove the portion 12C and result in the silicon substrate 12B. The step of FIG. 10F that follows the step of FIG. 10E is the same as that of FIG. 9E.

The third embodiment provides the same effects as those of the second embodiment.

(Fourth Embodiment)

A fourth embodiment of the present invention provides yet another method of fabricating the SAW devices 20. The fourth embodiment has an etching step that is carried out prior to the cutting step shown in FIG. 9E or FIG. 10F.

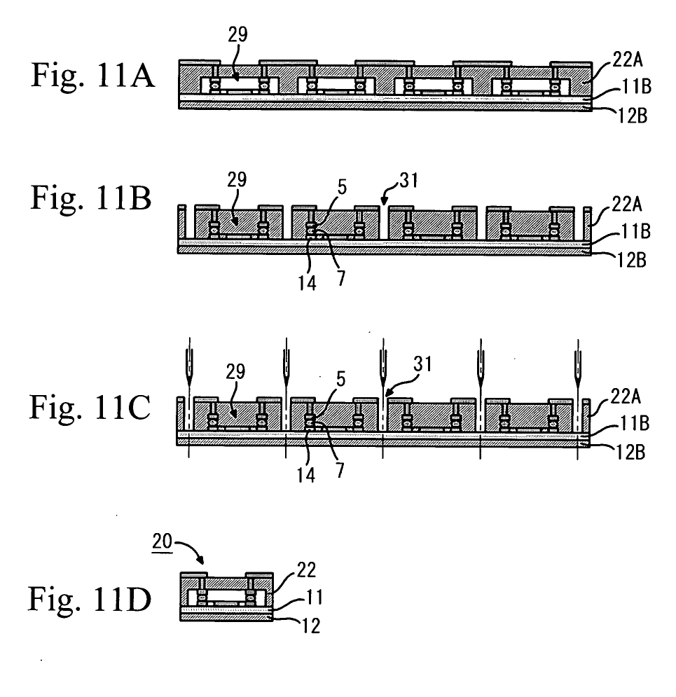

FIG. 11A shows the joined substrate composed of the silicon substrate 22A, the piezoelectric substrate 11B and the silicon substrate 12B available prior to the cutting step of FIG. 9E or FIG. 10F. The joined substrate shown in FIG. 11A can be produced by the same process as that of the second or third embodiment.

According to the fourth embodiment, as shown in FIG. 11B, the joined substrate is etched so as to form grooves 31 located at the positions of cutting by the dicing blade or laser beam. In FIG. 11B, the grooves 31 reach the piezoelectric substrate 11B. Thereafter, as shown in FIG. 11C, the joined substrate is cut into the individuals along the grooves 31 by using the dicing blade or laser, so that the separate SAW devices 20 each shown in FIG. 11D can be produced.

The use of the grooves 31 formed prior to cutting prevents the packages 22 from being broken. This improves the production yield and efficiency and contributes to downsizing of the packages 22 and SAW devices 20.

The present invention is not limited to the specifically described embodiments, and other embodiments, variations and modifications may be made without departing from the scope of the present invention.

The present invention is based on Japanese Patent Application No. 2003-090497 filed on Mar. 28, 2003, the entire disclosure of which is hereby incorporated by reference.

What is claimed is:

1. A method of fabricating a surface acoustic wave device comprising the steps of:
(a) joining a supporting substrate to a second surface of a piezoelectric substrate opposite to a first surface thereof;
(b) grinding and polishing the first surface of the piezoelectric substrate;
(c) grinding and polishing a third surface of the supporting substrate opposite to another surface thereof to which the second surface of the piezoelectric substrate is joined; and
(d) forming, on the first surface of the piezoelectric substrate, an on-chip pattern including comb-like electrodes and electrode pads.

2. The method as claimed in claim 1, wherein:
the step (d) forms the on-chip pattern so as to have patterns arranged two-dimensionally; and
the method further comprises a step of cutting a joined substrate having grinded and polished supporting substrate and piezoelectric substrate into parts each of which parts has a respective one of the patterns arranged two-dimensionally.

3. The method as claimed in claim 2, further comprising the steps of:
housing each of the parts into a respective cavity formed in a first substrate; and
sealing the respective cavity with a second substrate.

4. The method as claimed in claim 3, the step of sealing comprises a step of subjecting at least one of joining surfaces of the first and second substrates to a surface activation process that uses ion beams, neutralized high-energy atom beams, or plasma of inert gas or oxygen prior to joining.

5. The method as claimed in claim 1, further comprising a step (e) of joining the piezoelectric substrate to a first substrate having a cavity in which the on-chip pattern is housed so that the on-chip pattern can be hermetically sealed with the first substrate.

6. The method as claimed in claim 5, wherein the step (c) is performed after the step (e).

7. The method as claimed in claim 1, wherein the step (d) forms the on-chip pattern so as to have patterns arranged two-dimensionally; and
the method further comprises the steps of:
joining the piezoelectric substrate to a first substrate having cavities arranged two-dimensionally, each of which cavities houses a respective one of the patterns of the on-chip pattern; and
cutting the piezoelectric substrate, the supporting substrate and the first substrate into individuals each of which has a corresponding one of the cavities.

8. The method as claimed in claim 7, further comprising a step of etching the first substrate so as to form grooves at cutting positions at which the step of cutting are carried out.

9. The method as claimed in claim 5, further comprising a step of subjecting at least one of joining surfaces of the first substrate and the piezoelectric substrate to a surface activation process that uses ion beams, neutralized high-energy atom beams, or plasma of inert gas or oxygen prior to joining.

10. The method as claimed in claim 1, further comprising a step of subjecting at least one of joining surfaces of the piezoelectric substrate and the supporting substrate to a surface activation process that uses ion beams, neutralized high-energy atom beams, or plasma of inert gas or oxygen prior to joining.

11. The method as claimed in claim 1, wherein the supporting substrate is a silicon substrate.

12. The method as claimed in claim 1, wherein the supporting substrate is made of silicon having a resistivity of 100 Ω·m or greater.

13. The method as claimed in claim 1, wherein the piezoelectric substrate contains, as a major component, one of lithium tantalate and lithium niobate.

14. A surface acoustic wave device comprising:
a piezoelectric substrate having a first surface on which an on-chip pattern including comb-like electrodes and electrode pads is formed; and
a supporting substrate joined to a second surface of the piezoelectric substrate opposite to the first surface thereof,
at least one of the first surface of the piezoelectric substrate and a third surface of the supporting substrate opposite to a fourth surface thereof joined to the second surface of the piezoelectric substrate is a grinded and polished surface.

15. The surface acoustic wave device as claimed in claim 14, wherein at least one of the second surface of the piezoelectric substrate and the fourth surface of the supporting substrate has been subjected to a surface activation process.

16. The surface acoustic wave device as claimed in claim 14, further comprising:
a first substrate having a cavity that houses the piezoelectric substrate and the supporting substrate joined thereto; and
a second substrate that hermetically seals the cavity.

17. The surface acoustic wave device as claimed in claim 14, further comprising a first substrate having a cavity that houses the on-chip pattern, the first substrate being joined to the piezoelectric substrate so that the on-chip pattern is housed in the cavity.
